(19) United States
(12) Patent Application Publication
(10) Pub. No.: US 2025/0290862 A1
(43) Pub. Date: Sep. 18, 2025

(54) SUBSTRATE INSPECTION APPARATUS AND SUBSTRATE INSPECTION METHOD

(71) Applicant: Samsung Display Co., LTD., Yongin-si (KR)

(72) Inventors: Hee Gwan RYU, Yongin-si (KR); Young Hoon OH, Yongin-si (KR); Dae Han LEE, Yongin-si (KR); A Young LEE, Yongin-si (KR)

(73) Assignee: Samsung Display Co., LTD., Yongin-si (KR)

(21) Appl. No.: 18/910,356

(22) Filed: Oct. 9, 2024

(30) Foreign Application Priority Data
Mar. 14, 2024 (KR) 10-2024-0035880

(51) Int. Cl. G01N 21/88

(52) U.S. Cl. CPC G01N 21/8851; G01N 2021/8887

(57) ABSTRACT

A substrate inspection method includes selecting an optimum inspection value using a test substrate, and determining at least one of crystallization degree and abnormal crystallization of a target substrate using the optimum inspection value. The selecting of the optimum inspection value includes capturing a focus region located in at least a portion of the test substrate, quantifying at least one of the crystallization degree and the abnormal crystallization of the test substrate, and selecting at least one of an optimum process energy density value (OPED) and an optimum abnormal crystallization determination value (OACD) as the optimum inspection value.

### CROSS-REFERENCE TO RELATED APPLICATION(S)

This application claims priority to and benefits of Korean Patent Application No. 10-2024-0035880 under 35 U.S.C. § 119, filed on Mar. 14, 2024 in the Korean Intellectual Property Office, the entire contents of which is incorporated herein by reference.

### BACKGROUND

### 1. Technical Field

This disclosure relates to a substrate inspection apparatus and a substrate inspection method.

### 2. Description of the Related Art

As the information society develops, demands for display devices for displaying images are increasing in various forms. A display device may include a transistor for driving a light emitting element and a polysilicon crystal layer for placing the transistor.

The crystallization quality of a polysilicon substrate, which is a substrate including the polysilicon crystal layer, is closely related to the electron mobility of the transistor of the display device and is a factor in the quality of the display device.

Among the factors that determine the crystallization quality of the polysilicon substrate, crystallization degree may be greatly affected by the energy (or crystallization energy) of a laser that crystallizes amorphous silicon into polysilicon. For example, in case that the crystallization energy is low, grain formation of crystals may not be sufficient. Therefore, the electron mobility of the above-described transistor may be reduced, causing deterioration of the quality of the display device.

In addition, among the factors that determine the crystallization quality of the polysilicon substrate, abnormal crystallization may be greatly affected by a design method such as the placement and structure of an optical system included in a laser device that crystallizes amorphous silicon into polysilicon. For example, if some components of the optical system are misaligned in a specific direction, abnormal crystallization such as diagonal mura may occur. Accordingly, the electron mobility of the transistor may be reduced, causing deterioration of the quality of the display device.

Therefore, it is desirable to objectify and quantify the crystallization quality of the polysilicon substrate, such as crystallization degree and abnormal crystallization.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a substrate inspection apparatus which can inspect the crystallization degree and abnormal crystallization of a polysilicon substrate.

Aspects of the disclosure also provide a substrate inspection method which can quantify crystallization degree and abnormal crystallization.

However, aspects of the disclosure are not restricted to those set forth herein. The above and other aspects of the disclosure will become more apparent to one of ordinary skill in the art to which the disclosure pertains by referencing the detailed description of the disclosure given below.

According to an aspect of the disclosure, there is provided a substrate inspection method. The method may include selecting an optimum inspection value using a test substrate, and determining at least one of crystallization degree and abnormal crystallization of a target substrate using the optimum inspection value. The selecting of the optimum inspection value may include capturing a focus region located in at least a portion of the test substrate, quantifying at least one of the crystallization degree and the abnormal crystallization of the test substrate, and selecting at least one of an optimum process energy density value (OPED) and an optimum abnormal crystallization determination value (OACD) as the optimum inspection value.

In an embodiment, the quantifying of the at least one of the crystallization degree and the abnormal crystallization of the test substrate may include quantifying the abnormal crystallization, and the quantifying of the abnormal crystallization may include extracting a color table value and calculating a statistical value using the color table value.

In an embodiment, a color table used in the extracting of the color table value may be at least one of an RGB color table, a gray color table, a YCbCr color table, and an HSV color table.

In an embodiment, the calculating of the statistical value may include extracting line integral data for each angle in the focus region, extracting two or more trend lines of the line integral data for each angle, and calculating a statistical value of the two or more trend lines.

In an embodiment, the line integral data may include data obtained by adding color table values of pixels located at a same position in extension lines, the extension lines may extend at a same angle in the focus region and are arranged side by side with each other in a direction different from the angle.

In an embodiment, the line integral data may be extracted for each component of the color table.

In an embodiment, each of the two or more trend lines may be a graph of a function generated by connecting a point corresponding to an average of every n pieces of data included in the line integral data, wherein n is a natural number.

In an embodiment, the two or more trend lines may include a first trend line and a second trend line, the first trend line may be a graph of a function generated by connecting a point corresponding to an average of every x pieces of data, the second trend line may be a graph of a function generated by connecting a point corresponding to an average of every y pieces of data, and x and y may be natural numbers equal to or less than n and may be derived from a case where a ratio of a statistical value of a normal substrate among test substrates to a statistical value of an abnormal substrate among the test substrates is the smallest.

In an embodiment, the statistical value may be calculated using the squares of deviations between the two or more trend lines.

In an embodiment, the statistical value may be at least one of the average, standard deviation, maximum value, and minimum value of the squares of the deviations between the two or more trend lines.

In an embodiment, the selecting of the optimum inspection value may further include manufacturing the test substrate, the determining of the at least any of the crystallization degree and abnormal crystallization of the target substrate may include manufacturing the target substrate, and the test substrate and the target substrate may include polysilicon formed by a laser annealer.

In an embodiment, in the manufacturing of the target substrate, crystallization energy of the laser annealer may use the OPED.

In an embodiment, the determining of the at least any of the crystallization degree and abnormal crystallization of the target substrate may include capturing a focus region located on at least a portion of the target substrate, and quantifying at least any of crystallization degree and abnormal crystallization of the target substrate. The capturing of the focus region of the target substrate may be performed in a same manner as the capturing of the focus region of the test substrate, and the quantifying of the at least any of the crystallization degree and abnormal crystallization of the target substrate may be performed in a same manner as the quantifying of the at least any of the crystallization degree and abnormal crystallization of the test substrate.

According to another aspect of the disclosure, there is provided a substrate treatment apparatus. The apparatus may include an annealer which crystallizes amorphous silicon on a substrate into polysilicon, an imaging assembly which captures a focus region located in at least a portion of the polysilicon, and a controller which analyzes an image provided by the imaging assembly. The imaging assembly may include a dark field microscope and a differential interference contrast microscope.

In an embodiment, the dark field microscope may include a first light source, a first reflector, a guide, a first objective lens, a first tube lens, and a first camera.

In an embodiment, the differential interference contrast microscope may include a second light source, a second reflector, a prism, a second objective lens, a second tube lens, and a second camera.

In an embodiment, the prism may include a refractive prism, and the refractive prism may separate light incident from the second light source into at least two beams.

In an embodiment, the at least two beams separated by the prism may be reflected at different points in the focus region.

In an embodiment, the dark field microscope may include a first light source, a first reflector, a guide, a first objective lens, a first tube lens and a first camera, and the first camera and the second camera may be configured as one camera.

In an embodiment, the first light source and the second light source, the first reflector and the second reflector, the first objective lens and the second objective lens, and the first tube lens and the second tube lens may be configured as one light source, one reflector, one objective lens, and one tube lens, respectively.

A substrate inspection apparatus according to an embodiment of the disclosure can inspect the crystallization degree and abnormal crystallization of a polysilicon substrate.

A substrate inspection method according to an embodiment of the disclosure can quantify crystallization degree and abnormal crystallization.

However, the effects of the disclosure are not restricted to the one set forth herein. The above and other effects of the disclosure will become more apparent to one of ordinary skill in the art to which the disclosure pertains.

### BRIEF DESCRIPTION OF THE DRAWINGS

Hereinafter, embodiments of the disclosure will be described in detail with reference to the accompanying drawings.

These and/or other aspects will become apparent and more readily appreciated from the following description of the embodiments, taken in conjunction with the accompanying drawings in which:

FIG. 1 is a flowchart illustrating a substrate inspection method according to an embodiment;

FIG. 2 is a flowchart illustrating detailed operations of operation S100 of FIG. 1;

FIG. 3 is a flowchart illustrating detailed operations of operation S200 of FIG. 1;

FIG. 4 is a flowchart illustrating detailed operations of operation S130 of FIG. 2 and operation S230 of FIG. 3;

FIG. 5 is a flowchart illustrating detailed operations of operations S131 and S231 of FIG. 4;

FIG. 6 is a flowchart illustrating detailed operations of operations S132 and S232 of FIG. 4;

FIG. 7 is a schematic perspective view of an annealing device of a substrate inspection apparatus;

FIG. 8 is a schematic cross-sectional view of a dark field microscope of the substrate inspection apparatus;

FIG. 9 is a schematic cross-sectional view of a differential interference contrast microscope of the substrate inspection apparatus;

FIG. 10 is a schematic plan view illustrating focus regions of a polysilicon test substrate of FIG. 7;

FIG. 11 is a schematic block diagram of a control unit of the substrate inspection apparatus;

FIG. 12 is a schematic example diagram illustrating a color table used to extract a color table value in operation S131a of FIG. 5 and operation S132a of FIG. 6;

FIG. 13 is an enlarged schematic perspective view of some of the focus regions of the polysilicon test substrate;

FIGS. 14 and 15 are schematic diagrams comparing crystallization energy sections that affect the extracting of the color table value in operation S131a of FIG. 5 and operation S132a of FIG. 6;

FIG. 16 is a schematic diagram illustrating the change in incident angle of light according to the hillock height of a polysilicon crystal;

FIG. 17 is a schematic diagram illustrating constructive interference of first reflected beams reflected from a first hillock of FIG. 16;

FIG. 18 is a schematic diagram illustrating constructive interference of second reflected beams reflected from a second hillock of FIG. 16;

FIG. 19 is a schematic graph illustrating the change in constructive interference wavelength with respect to diffraction angle;

FIG. 20 is a schematic graph illustrating the change in crystallization degree value with respect to the intensity of crystallization energy;

FIGS. 21 and 22 are schematic diagrams illustrating the extracting of line integral data in operation S132b of FIG. 6;

FIGS. 23 and 24 are schematic graphs illustrating a trend line of line integral data in operation S132c of FIG. 6;

FIG. 25 is a schematic graph illustrating a statistical value of trend lines in operation S132d of FIG. 6;

FIG. 26 is a schematic graph and a schematic table illustrating the statistical value of the trend lines in operation S132d of FIG. 6;

FIG. 27 is a schematic table illustrating a method of selecting a trend line of line integral data in operation S132c of FIG. 6;

FIG. 28 is a schematic perspective view illustrating operation S210 of FIG. 3;

FIG. 29 is a schematic plan view illustrating focus regions of a polysilicon target substrate of FIG. 28;

FIG. 30 is a schematic graph of an image of a focus region captured in operation S220 of FIG. 3;

FIG. 31 is a schematic table showing crystallization energy, crystallization degree values, and crystallization pictures of various samples of polysilicon target substrates; and

FIG. 32 is a schematic diagram comparing a captured image of a focus region of an abnormal crystallization substrate and a captured image of a focus region of a normal substrate.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” or “substantially” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

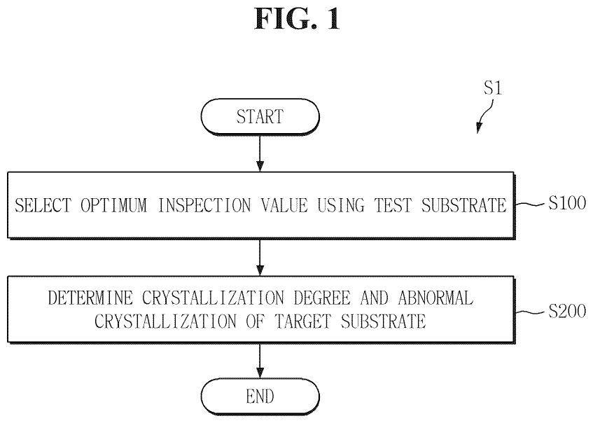

FIG. 1 is a flowchart illustrating a substrate inspection method S1 according to an embodiment.

Referring to FIG. 1, the substrate inspection method S1 according to an embodiment may be a method of inspecting the crystallization quality of a polysilicon substrate. Factors that determine the crystallization quality of the polysilicon substrate may include crystallization degree and abnormal crystallization. In some embodiments, the substrate inspection method S1 may be a method of inspecting the crystallization degree and abnormal crystallization of a polysilicon substrate.

The substrate inspection method S1 may include selecting an optimum inspection value using a test substrate (operation S100) and determining the crystallization degree and abnormal crystallization of a target substrate (operation S200).

In the selecting of the optimum inspection value using the test substrate (operation S100), an optimum inspection value for determining the crystallization degree of a polysilicon substrate and an optimum inspection value for determining the abnormal crystallization of the polysilicon substrate may be selected.

The optimum inspection value for determining the crystallization degree of the polysilicon substrate may be an optimum process energy density value (OPED). The optimum inspection value for determining the abnormal crystallization of the polysilicon substrate may be an optimum abnormal crystallization determination value (OACD).

In the determining of the crystallization degree and abnormal crystallization of the target substrate (operation S200), an inspection value of the target substrate may be compared with the optimum inspection value previously selected using the test substrate.

For example, to determine the crystallization degree of the target substrate, a process energy density value (PED) of the target substrate may be compared with the previously selected OPED. To determine the abnormal crystallization of the target substrate, an abnormal crystallization determination value (ACD) of the target substrate may be compared with the previously selected OACD.

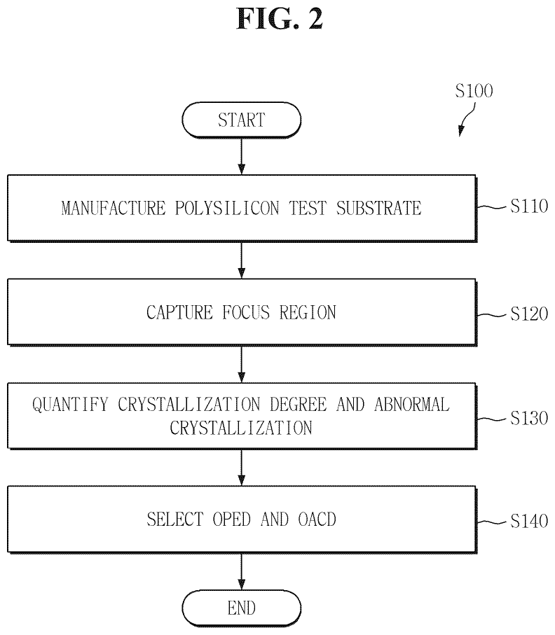

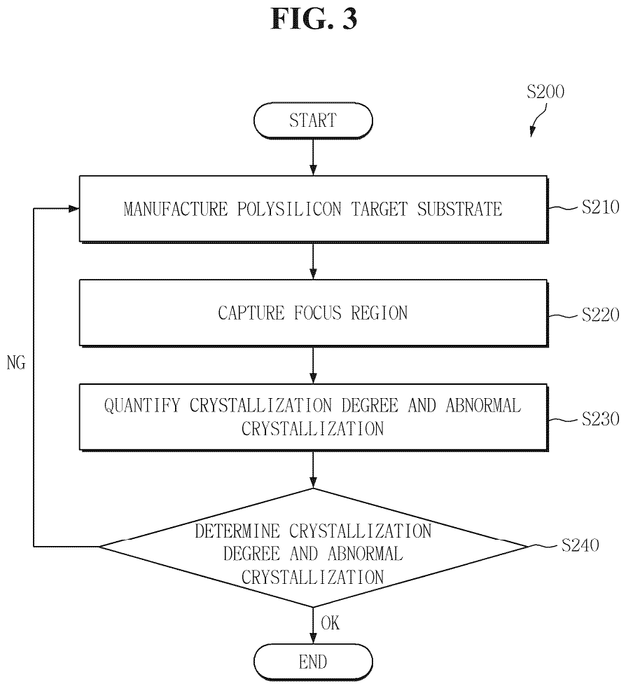

FIG. 2 is a flowchart illustrating detailed operations of operation S100 of FIG. 1. FIG. 3 is a flowchart illustrating detailed operations of operation S200 of FIG. 1.

Referring to FIGS. 2 and 3 in addition to FIG. 1, as illustrated in FIG. 2, the selecting of the optimum inspection value using the test substrate (operation S100) may include manufacturing a polysilicon test substrate (operation S110), capturing a focus region (operation S120), quantifying crystallization degree and abnormal crystallization (operation S130), and selecting an OPED and an OACD (operation S140).

As illustrated in FIG. 3, the determining of the crystallization degree and abnormal crystallization of the target substrate (operation S200) may include manufacturing a polysilicon target substrate (operation S210), capturing a focus region (operation S220), quantifying crystallization degree and abnormal crystallization (operation S230), and determining the crystallization degree and the abnormal crystallization (operation S240).

The selecting of the optimum inspection value using the test substrate (operation S100) and, as illustrated in FIG. 3, the determining of the crystallization degree and abnormal crystallization of the target substrate (operation S200) may be performed by a substrate inspection apparatus.

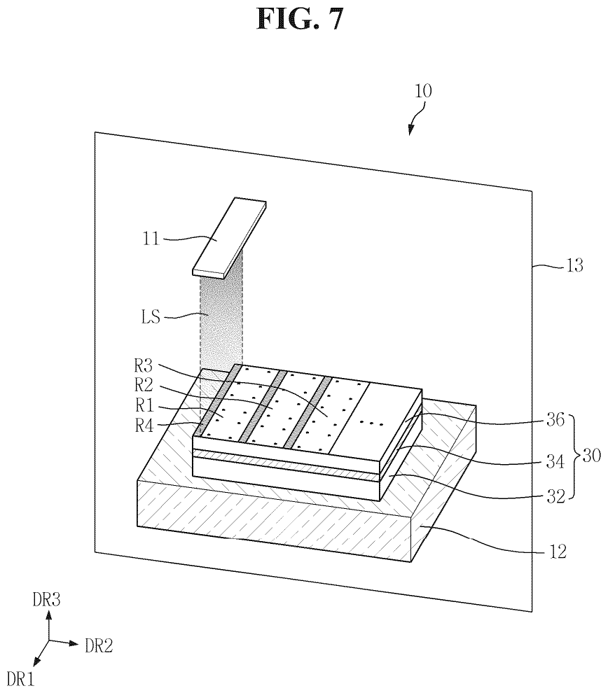

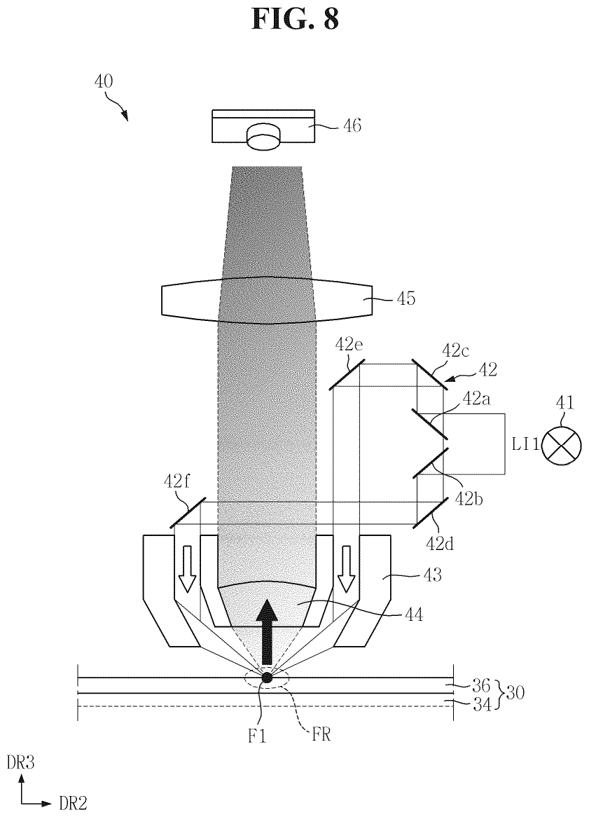

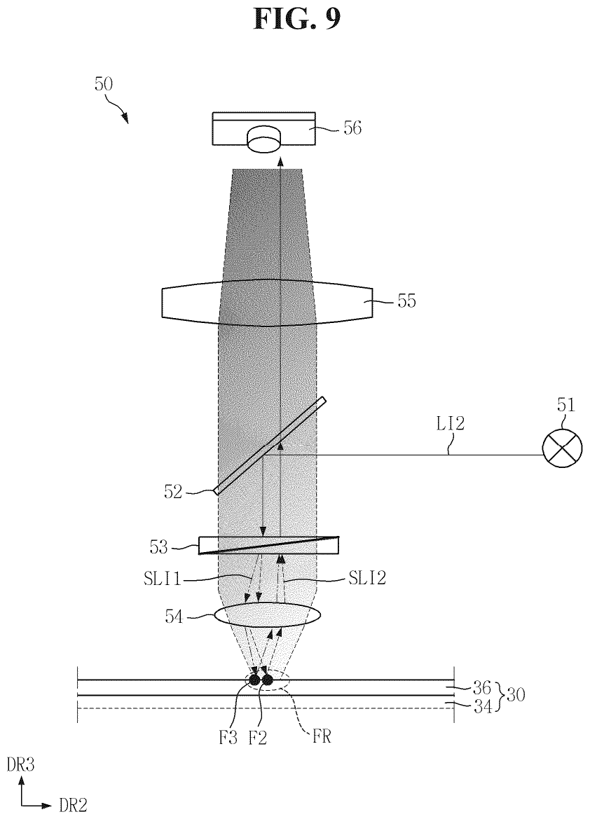

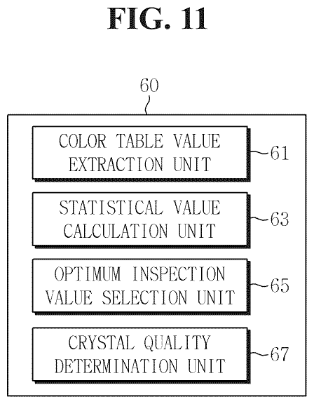

The substrate inspection apparatus may include an annealing device (annealer) 10 (see FIG. 7) which manufactures a test substrate and a target substrate in operations S110 and S210, respectively, an imaging device (assembly) 40 and 50 (see FIGS. 8 and 9) which captures a focus region in operations S120 and S220, and a control unit (controller) 60 (see FIG. 11) which quantifies crystallization degree and abnormal crystallization in operations S130 and S230, selects an OPED and an OACD in operation S140, and determines the crystallization degree and the abnormal crystallization in operation S240.

The substrate inspection apparatus will be described later with reference to FIGS. 7 through 11.

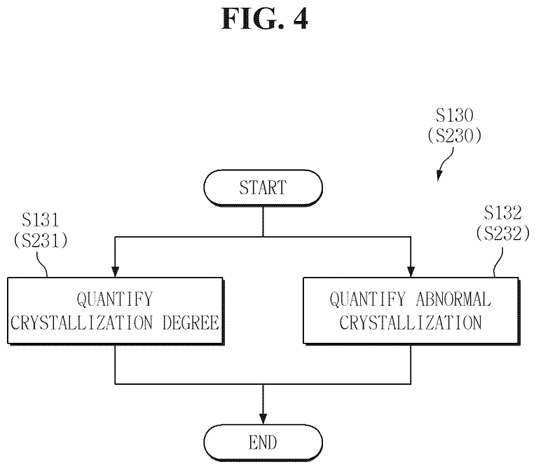

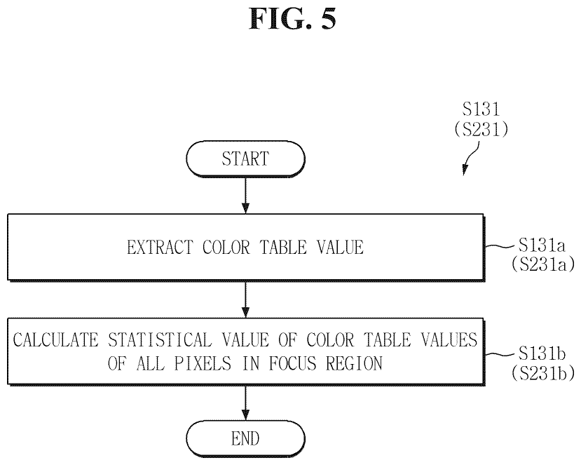

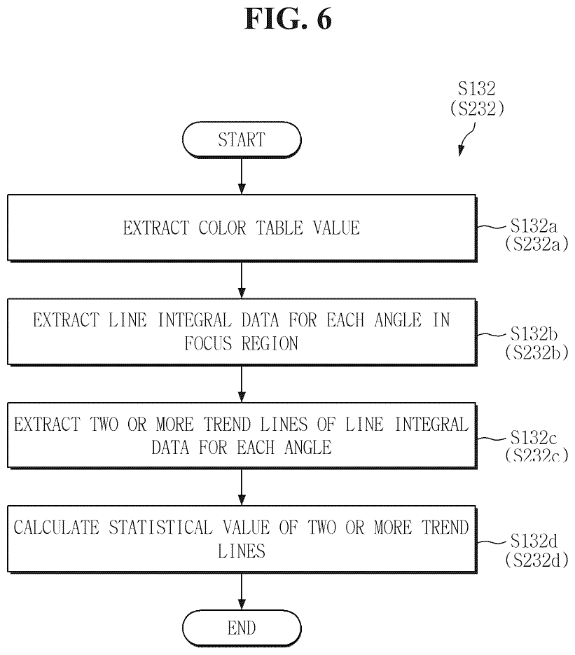

FIG. 4 is a flowchart illustrating detailed operations of operation S130 of FIG. 2 and operation S230 of FIG. 3. FIG. 5 is a flowchart illustrating detailed operations of operations S131 and S231 of FIG. 4. FIG. 6 is a flowchart illustrating detailed operations of operations S132 and S232 of FIG. 4.

Referring to FIGS. 4 through 6 in addition to FIGS. 1 through 3, as illustrated in FIG. 4, the quantifying of the crystallization degree and the abnormal crystallization (operations S130 and S230) may include quantifying crystallization degree (operations S131 and S231) and quantifying abnormal crystallization (operations S132 and S232).

As illustrated in FIG. 5, the quantifying of the crystallization degree (operations S131 and S231) may include extracting a color table value (operations S131a and S231a) and calculating a statistical value of color table values of all pixels in the focus region (operations S131b and S231b).

As illustrated in FIG. 6, the quantifying of the abnormal crystallization (operations S132 and S232) may include extracting a color table value (operations S132a and S232a), extracting line integral data for each angle in the focus region (operations S132b and S232b), extracting two or more trend lines of the line integral data for each angle (operations S132c and S232c), and calculating a statistical value of the two or more trend lines (operations S132d and S232d).

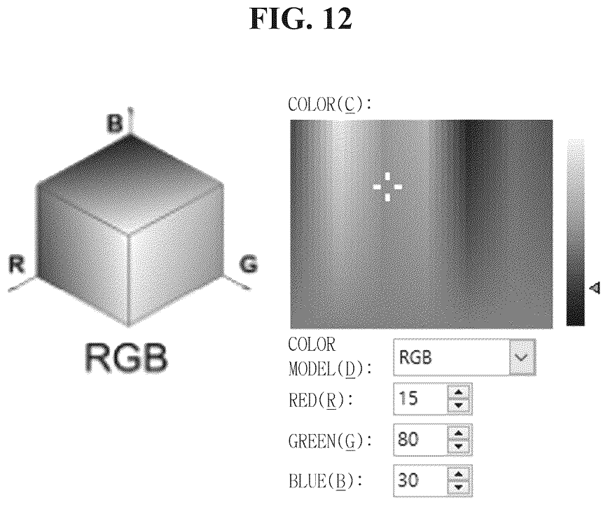

The detailed operations of the quantifying of the crystallization degree (operations S131 and S231) and the quantifying of the abnormal crystallization (operations S132 and S232) will be described later with reference to FIGS. 12 through 27.

The substrate inspection method S1 and the substrate inspection apparatus for performing the substrate inspection method S1 will now be described with reference to FIGS. 7 through 11.

FIG. 7 is a schematic perspective view of the annealing device 10 of the substrate inspection apparatus.

Referring to FIG. 7 in addition to FIGS. 2 and 3, the substrate inspection apparatus may include the annealing device 10 which manufactures a test substrate and a target substrate in operations S110 and S210, respectively.

The annealing device 10 may include a laser irradiation unit 11, a stage 12, and a chamber 13. The annealing device 10 may form polysilicon 36 by crystallizing amorphous silicon. The annealing device 10 may be an excimer laser annealing (ELA) crystallization facility.

The laser irradiation unit 11 may irradiate laser light LS to amorphous silicon. The stage 12 may provide a space where a base substrate 32 can be seated. The chamber 13 may define a reaction space where an annealing process can be performed.

The laser irradiation unit 11 may include a laser oscillator which generates the laser light LS and an optical system which adjusts a beam size and path of the laser light LS generated by the laser oscillator.

In the manufacturing of the polysilicon test substrate (operation S110), the annealing device 10 may manufacture a polysilicon test substrate 30. The polysilicon test substrate 30 may include the base substrate 32, a buffer layer 34, and the polysilicon 36. In some embodiments, the buffer layer 34 may be omitted.

The manufacturing of the polysilicon test substrate (operation S110) may include sequentially stacking the buffer layer 34 and amorphous silicon on the base substrate 32 and forming the polysilicon 36 by crystallizing the deposited amorphous silicon.

For example, the base substrate 32 may be placed on the stage 12 in the chamber 13. The buffer layer 34 and amorphous silicon may be placed on the base substrate 32. The buffer layer 34 and the amorphous silicon may be stacked by a deposition process, but the disclosure is not limited thereto. In case that the laser irradiation unit 11 irradiates the laser light LS to the amorphous silicon, the amorphous silicon may be crystallized to form the polysilicon 36.

Specifically, the laser light LS may be focused on the amorphous silicon. The laser light LS focused on the amorphous silicon may have a line shape extending along a first direction DR1 in plan view. The laser focusing area having a line shape in plan view may crystallize the amorphous silicon while moving along a second direction DR2.

In the drawing, the first direction DR1 and the second direction DR2 are horizontal directions and intersect each other. For example, the first direction DR1 and the second direction DR2 may be orthogonal to each other. In addition, a third direction DR3 may be a vertical direction intersecting the first direction DR1 and the second direction DR2, for example, orthogonal to the first direction DR1 and the second direction DR2. Unless otherwise defined, in the specification, a direction indicated by an arrow of each of the first through third directions DR1 through DR3 may be referred to as a first side, and the opposite direction may be referred to as a second side.

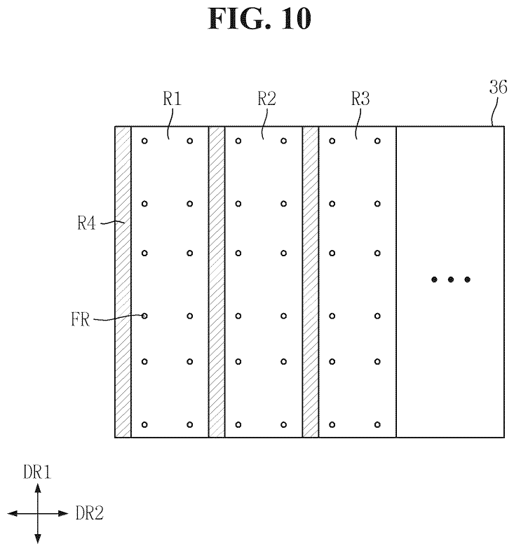

The polysilicon 36 of the test substrate 30 formed through the annealing device 10 may include multiple regions R1 through R4 formed by different crystallization energies, as illustrated in FIG. 7. For example, a first region R1, a second region R2, a third region R3, and a fourth region R4 may be formed by gradually decreasing crystallization energy in this order. The regions R1 through R4 will be described later with reference to FIG. 10.

FIG. 8 is a schematic cross-sectional view of a dark field microscope 40 of the substrate inspection apparatus. FIG. 9 is a schematic cross-sectional view of a differential interference contrast microscope 50 of the substrate inspection apparatus.

Referring to FIGS. 8 and 9 in addition to FIGS. 2 and 3, the substrate inspection apparatus may include the imaging device 40 and 50 which captures a focus region in operations S120 and S220. The imaging device 40 and 50 may include the dark field microscope 40 and the differential interference contrast microscope 50.

The dark field microscope 40 may include a first light source unit (light source) 41, a first reflection unit (reflector) 42, a guide unit (guide) 43, a first objective lens 44, a first tube lens 45, and a first camera 46. The differential interference contrast microscope 50 may include a second light source unit 51, a second reflection unit 52, a prism 53, a second objective lens 54, a second tube lens 55, and a second camera 56.

In some embodiments, the dark field microscope 40 and the differential interference contrast microscope 50 may constitute one imaging device 40 and 50. For example, the dark field microscope 40 and the differential interference contrast microscope 50 may be included in one imaging device 40 and 50. The imaging device 40 and 50 may be a multifunctional microscope that includes both the dark field microscope 40 and the differential interference contrast microscope 50.

In some embodiments, in case that the dark field microscope 40 and the differential interference contrast microscope 50 are included in one imaging device 40 and 50, the first light source unit 41 of the dark field microscope 40 and the second light source unit 51 of the differential interference contrast microscope 50 may be configured as one light source unit, the first objective lens 44 of the dark field microscope 40 and the second objective lens 54 of the differential interference contrast microscope 50 may be configured as one lens, the first tube lens 45 of the dark field microscope 40 and the second tube lens 55 of the differential interference contrast microscope 50 may be configured as one lens, and the first camera 46 of the dark field microscope 40 and the second camera 56 of the differential interference contrast microscope 50 may be configured as one camera. For example, the dark field microscope 40 and the differential interference contrast microscope 50 may share components that perform the same function.

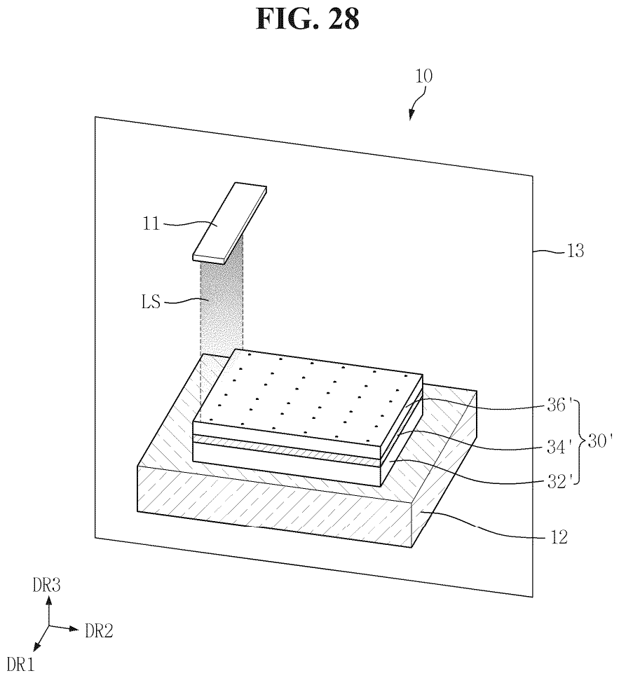

In the capturing of the focus region of the test substrate 30 (operation S120), the imaging device 40 and 50 may capture a focus region FR of the test substrate 30. In the capturing of the focus region of a target substrate 30′ (operation S220), the imaging device 40 and 50 may capture a focus region FR of the target substrate 30′ (see FIG. 28).

The capturing of the focus region (operations S120 and S220) may include enlarging focus regions FR using optical system components of the dark field microscope 40 and the differential interference contrast microscope 50 and capturing the enlarged focus regions FR using a camera.

For example, in the enlarging of the focus regions FR using the dark field microscope 40, first light LI1 may be emitted from the first light source unit 41 to the second side in the second direction DR2 and provided to a focus region FR through a first optical system. The first light LI1 reflected from the focus region FR may pass through the first objective lens 44 and the first tube lens 45 and reach the first camera 46. As illustrated in FIG. 8, the first optical system may include the first reflection unit 42 which changes the path of the first light LI1 emitted from the first light source unit 41 through reflection and the guide unit 43 which guides the first light LI1 whose optical path has been changed by the first reflection unit 42.

The first reflection unit 42 may separate the first light LI1 emitted from the first light source unit 41 into two beams. For example, the first reflection unit 42 may include a first sub-reflector 42a, a second sub-reflector 42b, a third sub-reflector 42c, a fourth sub-reflector 42d, a fifth sub-reflector 42c, and a sixth sub-reflector 42f.

The first light LI1 emitted from the first light source unit 41 may be separated into first light LI1 travelling to the first side in the third direction DR3 through the first sub-reflector 42a and first light LI1 travelling to the second side in the third direction DR3 through the second sub-reflector 42b located below the first sub-reflector 42a. The first light LI1 travelling to the first side in the third direction DR3 may be reflected to the second side in the second direction DR2 through the third sub-reflector 42c, and the first light LI1 travelling to the second side in the third direction DR3 may be reflected to the second side in the second direction DR2 through the fourth sub-reflector 42d. The first light LI1 reflected to the second side in the second direction DR2 through the third sub-reflector 42c may be reflected to the second side in the third direction DR3 through the fifth sub-reflector 42e, and the first light LI1 reflected to the second side in the second direction DR2 through the fourth sub-reflector 42d may be reflected to the second side in the third direction DR3 through the sixth sub-reflector 42f. The first light LI1 reflected to the second side in the third direction DR3 through the fifth sub-reflector 42e and the first light LI1 reflected to the second side in the third direction DR3 through the sixth sub-reflector 42f may each be irradiated to a point F1 in the focus region FR through the guide unit 43. The first light LI1 reflected from the focus region FR may sequentially pass through the first objective lens 44 and the first tube lens 45 and reach the first camera 46.

In the enlarging of the focus regions FR using the differential interference contrast microscope 50, second light LI2 may be emitted from the second light source unit 51 to the second side in the second direction DR2 and provided to a focus region FR through a second optical system. The second light LI2 reflected from the focus region FR may pass through the second optical system again and reach the second camera 56. As illustrated in FIG. 9, the second optical system may include the second reflection unit 52 which changes the path of the second light LI2 emitted from the second light source unit 51 through reflection, the prism 53 which separates the second light LI2 into first sub-light SLI1 and second sub-light SLI2, and the second objective lens 54 which focuses the first sub-light SLI1 and the second sub-light SLI2 to one point in the focus region FR.

The prism 53 may separate the second light LI2 emitted from the second light source unit 51. In some embodiments, the prism 53 may be a refractive prism.

For example, the second light LI2 incident on the prism 53 may be separated by wavelength due to a different refractive index according to the wavelength. The first sub-light SLI1 and the second sub-light SLI2 separated from each other may be respectively focused and incident on different points F2 and F3 in the focus region FR by the second objective lens 54. The first sub-light SLI1 and the second sub-light SLI2 incident on different points F2 and F3, respectively, may pass through the second objective lens 54 and the prism 53 again and thus may be combined into one second light LI2. The combined second light LI2 may pass through the second tube lens 55 and reach the second camera 56.

The dark field microscope 40 may obtain an image of a high-contrast surface shape. The differential interference contrast microscope 50 may obtain a clearer image by making the surface shape stand out in relief by utilizing a differential interference effect. Since the substrate inspection apparatus according to an embodiment may include both the dark field microscope 40 and the differential interference contrast microscope 50 as an imaging device, the substrate inspection apparatus can obtain a high-resolution, clear image of the crystal shape of the polysilicon 36.

FIG. 10 is a schematic plan view illustrating focus regions FR of the polysilicon test substrate 30 of FIG. 7.

Referring to FIG. 10 in addition to FIG. 7, multiple focus regions FR may be defined in the polysilicon 36 of the polysilicon test substrate 30. The focus regions FR refer to image capturing regions of the imaging device 40 and 50 and may be defined on a surface of the polysilicon 36.

In the drawing, thirty-six focus regions FR are illustrated. However, the disclosure is not limited thereto. The number of focus regions FR can be adjusted variously in consideration of the reliability and cost of crystallization quality inspection. For example, as the number of focus regions FR to be inspected increases, the reliability of crystallization quality inspection can be improved, and as the number of focus regions FR decreases, inspection time and inspection costs can be saved.

FIG. 11 is a schematic block diagram of the control unit 60 of the substrate inspection apparatus.

Referring to FIG. 11 in addition to FIGS. 4 through 6 and 10, the substrate inspection apparatus may include the control unit 60 which quantifies crystallization degree and abnormal crystallization in operations S130 and S230, selects an OPED and an OACD in operation S140, and determines the crystallization degree and the abnormal crystallization in operation S240.

The control unit 60 may include a color table value extraction unit 61, a statistical value calculation unit 63, an optimum inspection value selection unit 65, and a crystal quality determination unit 67.

In the quantifying of the crystallization degree and the abnormal crystallization (operations S130 and S230), the color table value extraction unit 61 may extract a color table value, and the statistical value calculation unit 63 may calculate a statistical value using the extracted color table value.

As illustrated in FIG. 4, the quantifying of the crystallization degree and the abnormal crystallization (operations S130 and S230) may include quantifying crystallization degree (operations S131 and S231) and quantifying abnormal crystallization (operations S132 and S232). The quantifying of the crystallization degree (operations S131 and S231) and the quantifying of the abnormal crystallization (operations S132 and S232) will be described later with reference to FIGS. 12 through 27.

In the selecting of the OPED and the OACD (operation S140), the optimum inspection value selection unit 65 may select an OPED and an OACD which are optimum inspection values by comparing calculated statistical values of abnormal and normal substrates among polysilicon test substrates 30. For example, the OPED and the OACD may be selected by comparing a statistical value such as an average value, maximum value, minimum value, and/or standard deviation of a normal substrate with a statistical value such as an average value, maximum value, minimum value, and/or standard deviation of an abnormal substrate.

In the determining of the crystallization degree and the abnormal crystallization (operation S240), the crystal quality determination unit 67 may determine crystallization degree and abnormal crystallization by comparing a PED and an ACD which are inspection values of a target substrate with the OPED and the OACD which are optimum inspection values. The determining of the crystallization degree and the abnormal crystallization (operation S240) will be described later with reference to FIGS. 28 through 32.

The quantifying of the crystallization degree (operations S131 and S231) will now be described with reference to FIGS. 12 through 20.

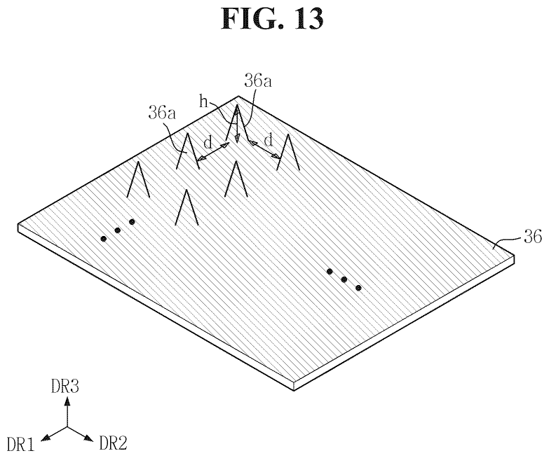

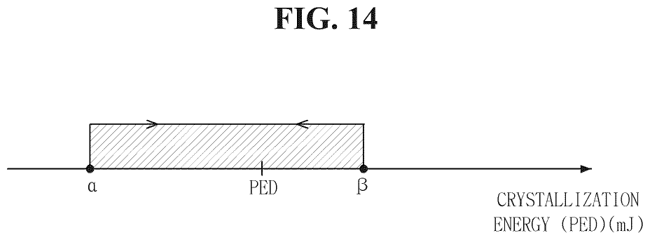

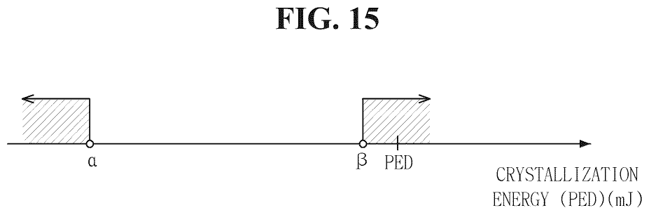

FIG. 12 is an example schematic diagram illustrating a color table used to extract a color table value in operation S131a of FIG. 5 and operation S132a of FIG. 6. FIG. 13 is an enlarged schematic perspective view of some of the focus regions FR of the polysilicon test substrate 30. FIGS. 14 and 15 are schematic diagrams comparing crystallization energy sections that affect the extracting of the color table value in operation S131a of FIG. 5 and operation S132a of FIG. 6.

Referring to FIGS. 12 through 15 in addition to FIGS. 5, 6 and 11, in the quantifying of the crystallization degree (operations S131 and S231), the color table value extraction unit 61 of the control unit 60 may extract a color table value (operations S131a and 231a of FIG. 5).

A color table refers to a table that defines and displays colors. The color table may include information about a variable for defining and displaying a color and information about a value of the variable. A color table value may include the information about the variable and the information about the value of the variable.

In the substrate inspection method S1 according to an embodiment, the type of color table may be determined by the type of variable. For example, if variables are three primary colors of red, green and blue (RGB), a color table may be an RGB color table. As another example, if the variables are two colors of black and white, the color table may be a gray color table. As another example, if the variables are brightness (Y) and chrominance components (Cb-Cr), the color table may be a YCbCr color table. As another example, if the variables are hue, saturation and value, the color table may be an HSV color table.

Although the RGB color table is illustrated in FIG. 12 as an example, the disclosure is not limited thereto. For ease of description, a case where a color table value is extracted using the RGB color table will be described below as an example.

As illustrated in FIG. 13, the surface of the polysilicon 36 may include multiple hillocks 36a rising to the first side in the third direction DR3. Each hillock 36a may have a predetermined or selected height h, and a distance d between adjacent hillocks 36a may be defined as a grain size.

The height h of each hillock 36a and the distance d between the hillocks 36a may be factors that affect a color table value extracted in the extracting of the color table value (operations S131a and S231a). That is, the extracting of the color table value (operations S131a and S231a) may be based on the height h of each of the hillocks 36a of the captured focus regions FR and the arrangement of the hillocks 36a.

As illustrated in FIGS. 14 and 15, if a PED is in a certain range, the extracting of the color table value (operations S131a and S231a) may be performed based on the height h of each of the hillocks 36a. If the PED is included outside the certain range, the extracting of the color table value (operations S131a and S231a) may be performed based on the arrangement of the hillocks 36a.

For example, if the PED is in the range of a to B, the extracting of the color table value (operations S131a and S231a) may be performed based on the height h of each of the hillocks 36a. If the PED is included in the range of less than a or greater than B, the extracting of the color table value (operations S131a and S231a) may be performed based on the arrangement of the hillocks 36a.

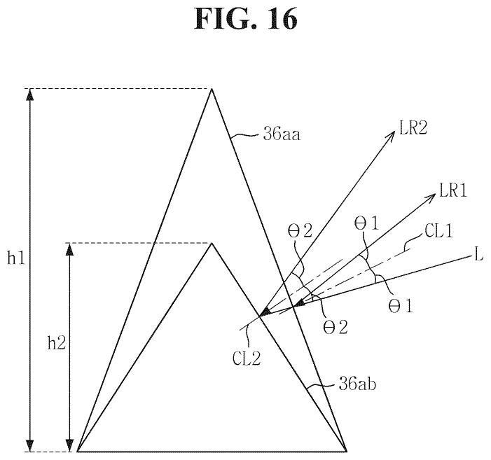

A mechanism of the extracting of the color table value performed based on the height h of each of the hillocks 36a in case that the distance d between the hillocks 36a is constant will now be described with reference to FIGS. 16 through 19.

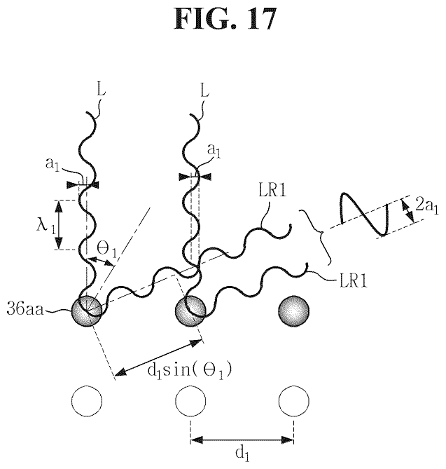

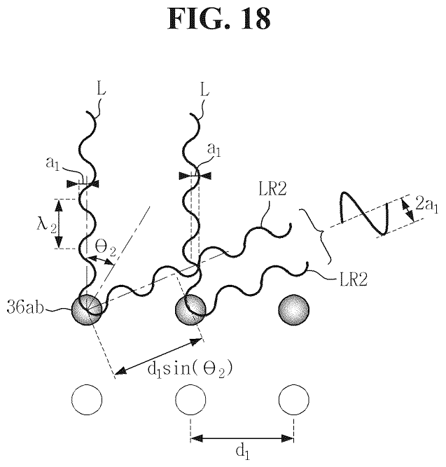

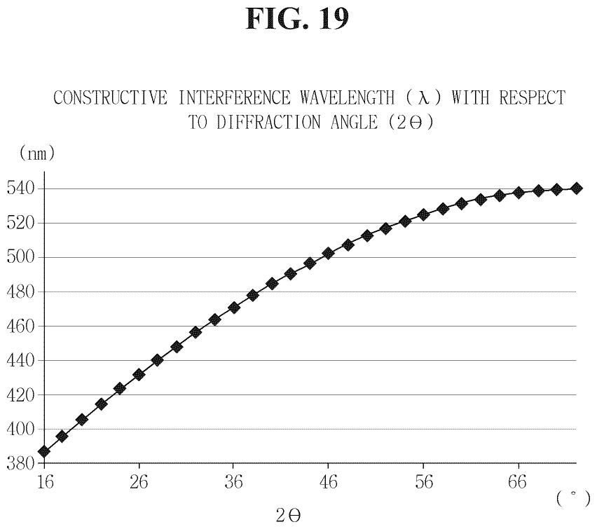

FIG. 16 is a schematic diagram illustrating the change in incident angle of light according to the hillock height of a polysilicon crystal. FIG. 17 is a schematic diagram illustrating constructive interference of first reflected beams reflected from a first hillock 36aa of FIG. 16. FIG. 18 is a schematic diagram illustrating constructive interference of second reflected beams reflected from a second hillock 36ab of FIG. 16. FIG. 19 is a schematic graph illustrating the change in constructive interference wavelength with respect to diffraction angle.

Referring to FIGS. 16 through 19, the hillocks 36a may include a first hillock 36aa having a first height h1 and a second hillock 36ab having a second height h2 smaller than the first height h1.

Even if a beam L is incident on the first hillock 36aa and the second hillock 36ab at the same angle, incident angles θ1 and θ2 of the beam L at contact surfaces with the first hillock 36aa and the second hillock 36ab may be different. For example, an incident angle θ1 of the first hillock 36aa having the first height h1 may be smaller than an incident angle θ2 of the second hillock 36ab having the second height h2.

The beam L may be reflected from the contact surfaces with the first hillock 36aa and the second hillock 36ab to become reflected beams LR1 and LR2. Reflection angles θ1 and θ2 of the reflected beams LR1 and LR2 may be equal to the incident angles θ1 and θ2, respectively.

An amplitude of the beam L is an in FIGS. 17 and 18, and a wavelength of the beam L is λ1 in FIGS. 17 and λ2 in FIG. 18. FIG. 17 shows a case where a focus region FR of the polysilicon 36 includes first hillocks 36aa, and FIG. 18 shows a case where the focus region FR of the polysilicon 36 includes second hillocks 36ab.

As illustrated in FIG. 17, a light wavelength that satisfies a condition for constructive interference (amplitude is 2ₐ₁) of beams L having an amplitude of a₁ and a reflection angle of θ1 in an adjacent first hillock 36aa may be λ1.

As illustrated in FIG. 18, a light wavelength that satisfies a condition for constructive interference (amplitude is 2ₐ₁) of beams L having an amplitude of a₁ and a reflection angle of θ2 in an adjacent second hillock 36ab may be λ2.

Here, the wavelengths λ1 and λ2 may satisfy Equation 1 below according to Bragg's law in low-energy electron diffraction (LEED).

n*λ=d*sin θ, Equation (1)

where n is a natural number, λ is the wavelength (λ1, λ2) of a beam L, d is a distance (d1, d2) (or grain size) between adjacent hillocks, and θ is a reflection angle (θ1, θ2).

The wavelength λ2 of a beam L which satisfies the condition for constructive interference in a second hillock 36ab may be greater than the wavelength λ1 of a beam L which satisfies the condition for constructive interference in a first hillock 36aa.

Therefore, a color table of beams LR1 which have been constructively interfered from the first hillocks 36aa may generally have colors in a low wavelength band, and a color table of beams LR2 which have been constructively interfered from the second hillocks 36ab may generally have colors in a high wavelength band.

As illustrated in FIG. 19, as a diffraction angle 2θ increases, a constructive interference wavelength λ may increase, and as the diffraction angle 2θ decreases, the constructive interference wavelength λ may decrease. That is, in a focus region FR with a high crystallization degree, the incident angle θ and the diffraction angle 2θ may be small because the height h of each hillock 36a is high. Therefore, light can have a color in a low wavelength band. On the other hand, in a focus region FR with a low crystallization degree, the incident angle θ and diffraction angle 2θ may be large because the height h of each hillock 36a is low. Therefore, light can have a color in a high wavelength band.

In the drawings, a mechanism of the extracting of the color table value based on the arrangement of the hillocks 36a or the distance d between the hillocks 36a in case that the height h of each of the hillocks 36a is constant is not illustrated. However, those of ordinary skill in the art will understand the relationship between the distance d between the hillocks 36a and the wavelength band for constructive interference based on Equation 1.

For example, if the distance d is large, the constructive interference wavelength λ may become large. Therefore, light can have a color in a high wavelength band. If the distance d is small, the constructive interference wavelength λ may become small. Therefore, light can have a color in a low wavelength band.

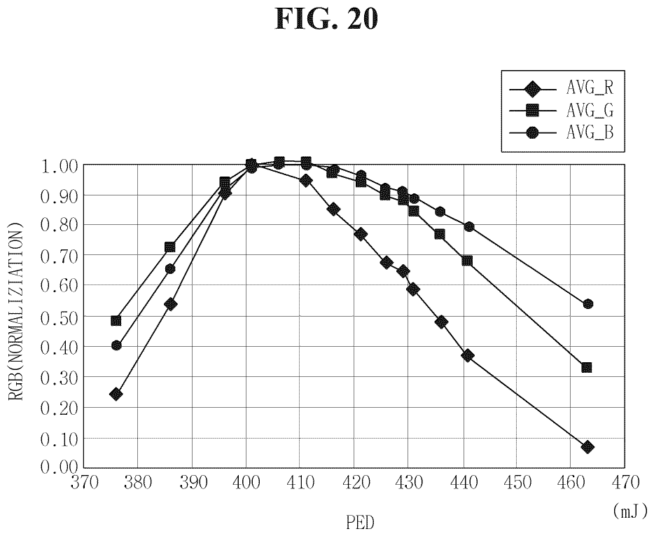

FIG. 20 is a schematic graph illustrating the change in crystallization degree value with respect to the intensity of crystallization energy.

Referring to FIG. 20 in addition to FIGS. 2 through 5 and 13, in the quantifying of the crystallization degree (operations S131 and S231), the statistical value calculation unit 63 of the control unit 60 may calculate a statistical value using color table values extracted from all pixels in a focus region FR (operations S131b and S231b of FIG. 5).

For example, in the calculating of the statistical value of the color table values of all pixels in the focus region (operations S131b and S231b), the statistical value calculation unit 63 of the control unit 60 may calculate a statistical value such as an average value, maximum value, minimum value, standard deviation, etc. of R values, G values, and B values extracted from all pixels in the focus region FR.

The horizontal axis of the graph illustrated in FIG. 20 represents PED. The vertical axis of the graph illustrated in FIG. 20 represents a value obtained by normalizing a statistical value of color table values, which are detected in the hillocks 36a crystallized by a corresponding PED, to a scale of 0 to 1. For example, the statistical value used in FIG. 20 is an average value of the color table values detected in the hillocks 36a. The statistical value calculation unit 63 may also use various statistical values such as maximum value, minimum value, and/or standard deviation.

The vertical axis of the graph illustrated in FIG. 20 represents R average data AVG_R which is the average of R component values of an RGB color table extracted from the hillocks 36a, B average data AVG_B which is the average of B component values, and G average data AVG_G which is the average of G component values.

In the selecting of the OPED and the OACD (operation S140), the optimum inspection value selection unit 65 of the control unit 60 may select an OPED by comparing the statistical values of an abnormal substrate and a normal substrate.

In the manufacturing of the polysilicon target substrate (operation S210) in the determining of the crystallization degree and abnormal crystallization of the target substrate (operation S200), a polysilicon target substrate 36′ (see FIG. 28) may be manufactured using laser light LS having a PED corresponding to the selected OPED.

The imaging device 40 and 50 may capture a focus region of the manufactured target substrate 36′ (see FIG. 28) (operation S220), and the color table value extraction unit 61 of the control unit 60 may quantify the crystallization degree of the target substrate 36′ (see FIG. 28) (operation S230).

In the determining of the crystallization degree and the abnormal crystallization (operation S240), the crystal quality determination unit 67 of the control unit 60 may determine the crystallization degree of the target substrate by comparing a statistical value of the target substrate with a statistical value corresponding to the OPED.

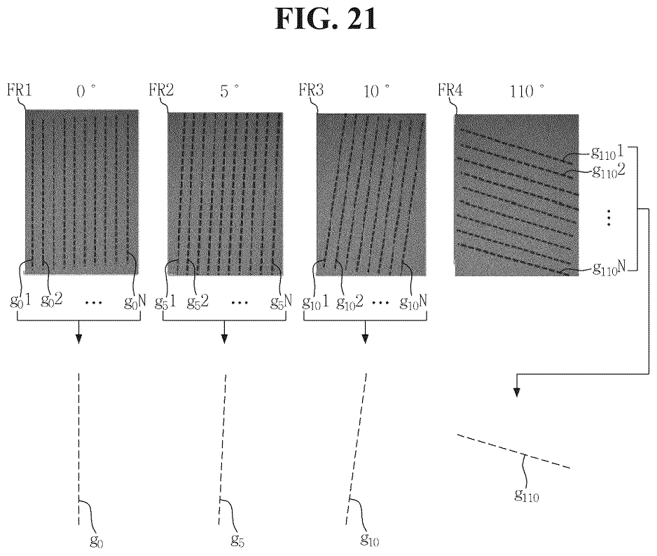

The quantifying of the abnormal crystallization (operations S132 and S232) will now be described with reference to FIGS. 21 through 27. A description of the same contents as those described in the quantifying of the crystallization degree (operations S131 and S231) with reference to FIGS. 12 through 20 will be omitted or given briefly, and differences will be described.

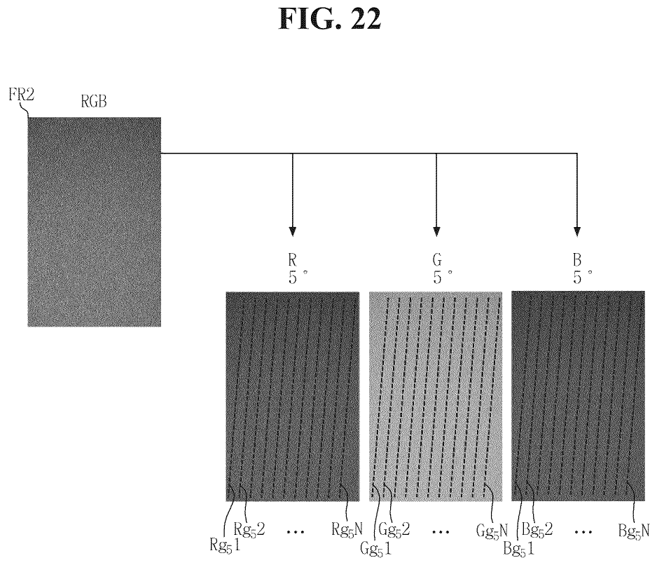

FIGS. 21 and 22 are schematic diagrams illustrating the extracting of the line integral data in operation S132b of FIG. 6.

Referring to FIGS. 21 and 22 in addition to FIGS. 5, 6 and 11, in the quantifying of the abnormal crystallization (operations S132 and S232), the color table value extraction unit 61 of the control unit 60 may extract a color table value (operations S132a and S232a of FIG. 5).

The extracting of the color table value (operations S132a and S232a) in the quantifying of the abnormal crystallization (operations S132 and S232) may be performed in substantially the same manner as the extracting of the color table value (operations S131a and S231a) in the quantifying of the crystallization degree (operations S131 and S231), and thus a description thereof will be omitted.

A method of calculating a statistical value in the quantifying of the abnormal crystallization (operations S132 and S232) may be different from the method of calculating a statistical value in the quantifying of the crystallization degree (operations S131 and S231).

For example, as described above with reference to FIG. 20, in the quantifying of the crystallization degree (operations S131 and S231), an average value of color table values extracted from all pixels in a focus region FR may be calculated. In other embodiments, a statistical value such as a maximum value, minimum value, standard deviation, etc. of the color table values extracted from all pixels may be calculated. That is, in the quantifying of the crystallization degree (operations S131 and S231), a statistical value of color table values extracted from the entire area of the focus region FR may be calculated. In the quantifying of the crystallization degree (operations S131 and S231), a statistical value of color table values extracted from two dimensions (plane dimension) may be calculated.

On the other hand, in the quantifying of the abnormal crystallization (operations S132 and S232), line integral data of color table values of pixels located on the same line in a focus region FR may be extracted, two or more trend lines of the line integral data may be extracted, and a statistical value of the two or more trend lines may be calculated. That is, in the quantifying of the abnormal crystallization (operations S132 and S232), a statistical value of trend lines of line integral data extracted from the same line rather than from the entire area of the focus region FR may be calculated. In the quantifying of the abnormal crystallization (operations S132 and S232), a statistical value of trend lines of line integral data extracted from one dimension (line dimension) may be calculated.

First, in the extracting of the line integral data for each angle in the focus region (operations S132b and S232b), the statistical value calculation unit 63 of the control unit 60 may extract line integral data.

The line integral data may include data obtained by adding color table values of pixels at the same position (e.g., the same row or the same column) in extension lines which extend at the same angle in a focus region FR and are arranged side by side with each other in a direction different from the angle.

For example, FIG. 21 is an example diagram illustrating focus regions FR, each including 640 pixels in the vertical direction and 480 pixels in the horizontal direction. A first focus region FR1 may include virtual extension lines g₀1, g₀2, . . . , g₀N inclined by 0 degrees with respect to the vertical direction. A second focus region FR2 may include virtual extension lines g₅1, g₅2, . . . , g₅N inclined by 5 degrees with respect to the vertical direction. A third focus region FR3 may include virtual extension lines g₁₀1, g₁₀2, . . . , g₁₀N inclined by 10 degrees with respect to the vertical direction. A fourth focus region FR4 may include virtual extension lines g₁₁₀1, g₁₁₀2, . . . , g₁₁₀N inclined by 110 degrees with respect to the vertical direction.

Although the first through fourth focus regions FR1 through FR4 of FIG. 21 show virtual extension lines inclined at different angles, they are just images captured of the same focus region FR.

The first focus region FR1 may be composed of multiple virtual extension lines g₀1, g₀2, . . . , g₀N, and each of the virtual extension lines g₀1, g₀2, . . . , g₀N may overlap multiple pixels. For example, the first focus region FR1 may be composed of about 480 virtual extension lines g₀1, g₀2, . . . , g₀N, and each of the virtual extension lines g₀1, g₀2, . . . , g₀N may overlap about 640 pixels.

As in the second focus region FR2, the third focus region FR3, and the fourth focus region FR4, the number of extension lines included in a focus region FR and the number of pixels overlapping each extension line may vary according to the angle of inclination with respect to the vertical direction. For ease of description, the following description will focus on the first focus region FR1.

The statistical value calculation unit 63 may line-integrate color table values included in the virtual extension lines g₀1, g₀2, . . . , g₀N extending at an angle of 0 degrees in the first focus region FR1.

For example, a first extension line g₀1 of the first focus region FR1 may include color table value data of each of 640 pixels located in a first column, a second extension line g₀2 of the first focus region FR1 may include color table value data of each of 640 pixels located in a second column, and an N^{th} extension line g₀N of the first focus region FR1 may include color table value data of each of 640 pixels located in an N^{th} column.

The statistical value calculation unit 63 may add all color table value data of pixels located in the same row of the first through N^{th} extension lines g₀1 through g₀N of the first focus region FR1. Accordingly, the first through N^{th} extension lines g₀1 through g₀N may be converted into first line integral data g₀.

The first line integral data g₀ may include first through M^{th} row data. The first row data may be obtained by adding color table values of 480 pixels located in a first row, and the M^{th} row data may be obtained by adding color table values of 480 pixels located in an M^{th} row. That is, the first line integral data g₀ may include about 640 color table value data. Here, row data is only an example name and may also be named column data depending on the angle of extension line.

In this way, the statistical value calculation unit 63 may extract line integral data for each angle. For example, second line integral data g₅ may be extracted by line-integrating extension lines inclined at 5 degrees in the second focus region FR2, third line integral data g₁₀ may be extracted by line-integrating extension lines inclined at 10 degrees in the third focus region FR3, and fourth line integral data g₁₁₀ may be extracted by line-integrating extension lines inclined at 110 degrees in the fourth focus region FR4.

In some embodiments, line integral data may be extracted for each component of a color table value. For example, in case that an RGB color table is used in the extracting of the color table value (operations S132a and S232a), line integral data may be extracted for each RGB component as well as for each angle.

As illustrated in FIG. 22, in case that the statistical value calculation unit 63 extracts the second line integral data g₅ by line-integrating extension lines inclined at 5 degrees in the second focus region FR2, the statistical value calculation unit may also extract line integral data from each of extension lines Rg₅1, Rg₅2, . . . , Rg₅N for an R component image, extension lines Gg₅1, Gg₅2, . . . , Gg₅N for a G component image, and extension lines Bg₅1, Bg₅2, . . . , Bg₅N for a B component image.

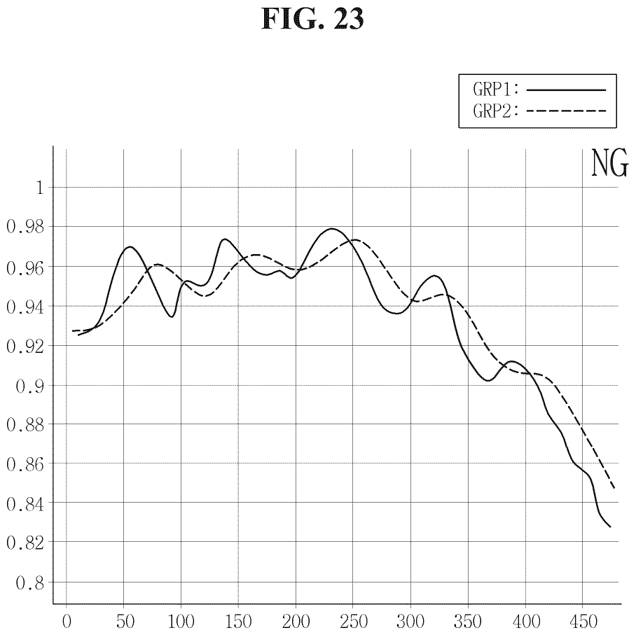

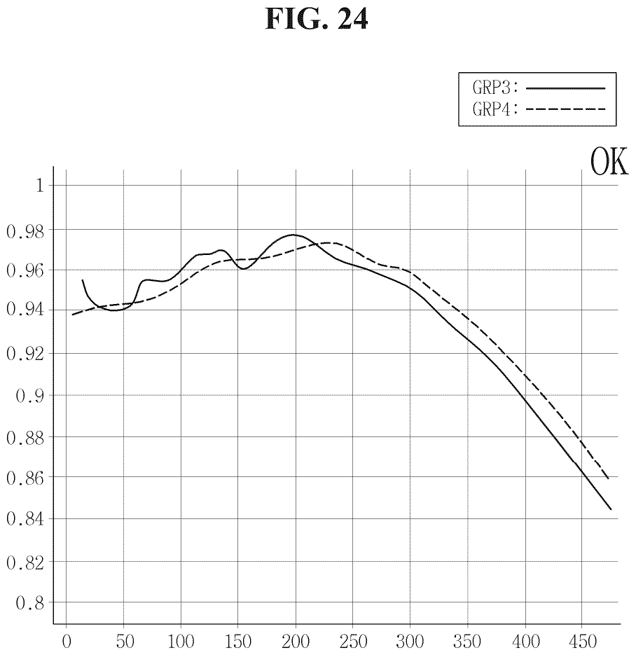

FIGS. 23 and 24 are schematic graphs illustrating a trend line of line integral data in operation S132c of FIG. 6.

Referring to FIGS. 23 and 24 in addition to FIGS. 21 and 22, in the extracting of the two or more trend lines of the line integral data for each angle (operations S132c and S232c), the statistical value calculation unit 63 of the control unit 60 may extract two or more trend lines for line integral data for each angle. For example, the statistical value calculation unit 63 may extract two or more trend lines for each of the first line integral data g₀ extracted from the first focus region FR1, the second line integral data g₅ extracted from the second focus region FR2, the third line integral data g₁₀ extracted from the third focus region FR3, and the fourth line integral data g₁₁₀ extracted from the fourth focus region FR4. For case of description, the following description will be based on the first line integral data g₀.

FIGS. 23 and 24 respectively show trend lines of line integral data of an abnormal substrate and trend lines of line integral data of a normal substrate.

The statistical value calculation unit 63 may extract a trend line based on row data (or column data) included in the first line integral data g₀. For example, as described above with reference to FIG. 21, the first line integral data g₀ may include the first through m^{th} row data. The first row data may be obtained by adding the color table values of the 480 pixels located in the first row, and the M^{th} row data may be obtained by adding the color table values of the 480 pixels located in the M^{th} row.

The horizontal axis of FIGS. 23 and 24 represents serial numbers of the first through M^{th} row data, and the vertical axis represents a value obtained by normalizing a color table value of each of the first through M^{th} row data to a scale of 0 to 1. The graphs of FIGS. 23 and 24 show trend lines extracted using about 462 pieces of row data among the first through M^{th} row data.

A trend line of line integral data is a graph of a function generated by connecting a point corresponding to the average of every certain number of pieces of data in the first through M^{th} row data. For example, a first graph GRP1 of FIG. 23 is a trend line extracted by connecting a point corresponding to the average of every 15 pieces of data in the first through M^{th} row data of the abnormal substrate, and a second graph GRP2 of FIG. 23 is a trend line extracted by connecting a point corresponding to the average of every 50 pieces of data in the first through M^{th} row data of the abnormal substrate. A third graph GRP3 of FIG. 24 is a trend line extracted by connecting a point corresponding to the average of every 15 pieces of data in the first through M^{th} row data of the normal substrate, and a fourth graph GRP4 of FIG. 24 is a trend line extracted by connecting a point corresponding to the average of every 50 pieces of data in the first through M^{th} row data of the normal substrate.

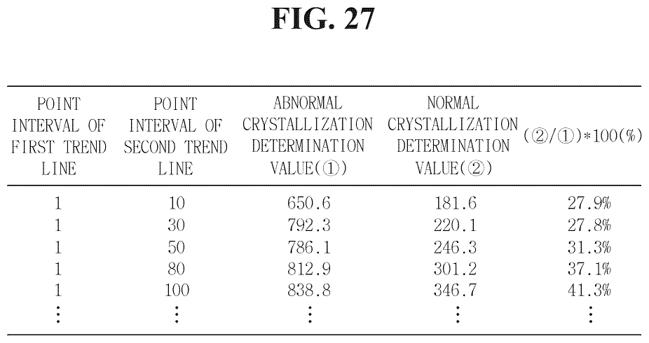

The number of pieces of row data selected to calculate the average can be changed variously. This will be described later with reference to FIG. 27.

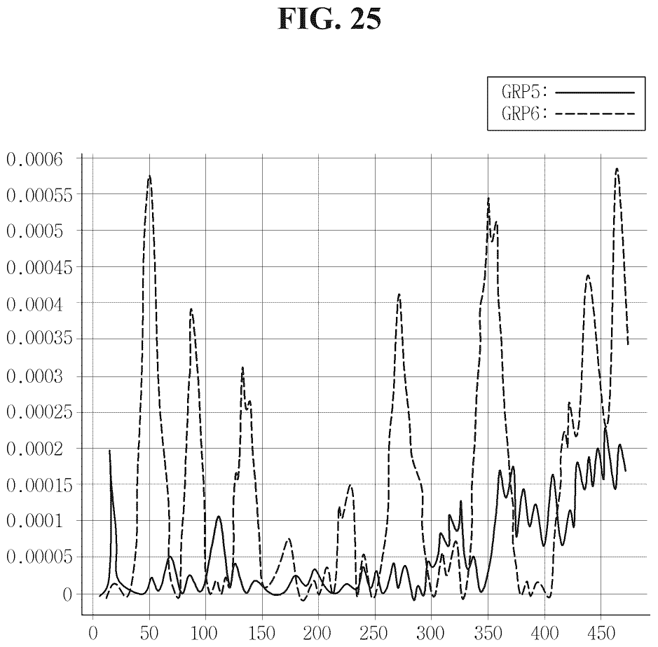

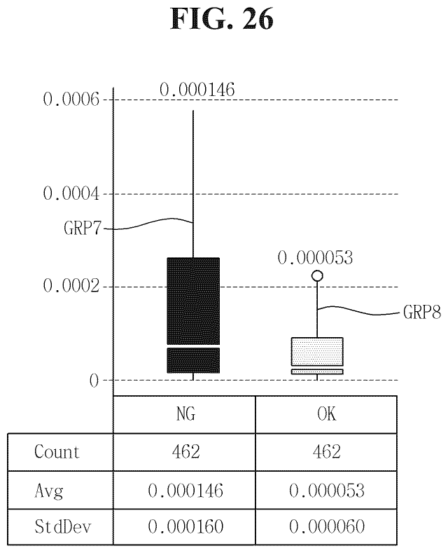

FIG. 25 is a schematic graph illustrating a statistical value of trend lines in operation S132d of FIG. 6. FIG. 26 is a schematic graph and a schematic table illustrating the statistical value of the trend lines in operation S132d of FIG. 6.

Referring to FIGS. 25 and 26 in addition to FIGS. 21 through 24, in the calculating of the statistical value of the two or more trend lines (operations S132d and S232d), the statistical value calculation unit 63 of the control unit 60 may calculate a statistical value using two or more trend lines extracted for line integral data for each angle.

A fifth graph GRP5 of FIG. 25 is a graph showing squared values of deviations between the first graph GRP1 and the second graph GRP2 in FIG. 23, and a sixth graph GRP6 of FIG. 25 is a graph showing squared values of deviations between the third graph GRP3 and the fourth graph GRP4 in FIG. 24.

A seventh graph GRP7 of FIG. 26 is a graph showing the degree of dispersion of data of the fifth graph GRP5, and an eighth graph GRP8 is a graph showing the degree of dispersion of data of the sixth graph GRP6.

Various statistical values can be used as a statistical value calculated by the statistical value calculation unit 63 using two or more trend lines extracted in the extracting of the two or more trend lines of the line integral data (operations 132c and 232c).

For example, as illustrated in FIGS. 25 and 26, the statistical value calculation unit 63 may obtain squared values of deviations of two trend lines and use the average or standard deviation of these values as a statistical value.

As illustrated in the seventh graph GRP7, in the case of the abnormal substrate, the average of the squared values of the deviations of the two trend lines is 0.000146. On the other hand, in the case of the normal substrate, the average of the squared values of the deviations of the two trend lines is 0.000053. In addition, in the case of the abnormal substrate, the standard deviation of the squared values of the deviations of the two trend lines is 0.000160. On the other hand, in the case of the normal substrate, the standard deviation of the squared values of the deviations of the two trend lines is 0.000060.

In addition to average value or standard deviation, the statistical value calculation unit 63 may also use various statistical values such as maximum value and minimum value.

In the selecting of the OPED and the OACD (operation S140) (see FIG. 2), the optimum inspection value selection unit 65 of the control unit 60 may select an OACD by comparing the statistical values of the abnormal substrate and the normal substrate. For example, an OACD may be selected in a range that includes the statistical values of the normal substrate but does not include the statistical values of the abnormal substrate by comparing the statistical values of the abnormal substrate and the statistical values of the normal substrate.

In the determining of the crystallization degree and the abnormal crystallization (operation S240) in the determining of the crystallization degree and abnormal crystallization of the target substrate (operation S200), the crystal quality determination unit 67 of the control unit 60 may determine the abnormal crystallization of the target substrate by comparing a statistical value of the target substrate with a statistical value corresponding to the OACD.

For example, if the statistical value of the target substrate exceeds the OACD or less than the OACD, the target substrate may be determined to be an abnormal substrate.

FIG. 27 is a schematic table illustrating a method of selecting a trend line of line integral data in operation S132c of FIG. 6.

Referring to FIG. 27 in addition to FIGS. 23 through 26, in case of extracting a trend line from line integral data, the statistical value calculation unit 63 may adjust the number of pieces of row data selected to calculate the average, thereby improving OACD determination sensitivity.

The table illustrated in FIG. 27 shows a ratio change between an abnormal crystallization determination value \textcircled{1} and a normal crystallization determination value \textcircled{2} according to point intervals of first and second trend lines. The abnormal crystallization determination value \textcircled{1} illustrated in FIG. 27 is a value obtained by multiplying an average value of the squares of deviations of two trend lines extracted from an abnormal substrate by 106, and the normal crystallization determination value \textcircled{2} illustrated in FIG. 27 is a value obtained by multiplying an average value of the squares of deviations of two trend lines extracted from a normal substrate by 106.

For example, if the average of row data is calculated at intervals of one point in the case of the first trend line and at intervals of 10 points in the case of the second trend line, the ratio of the normal crystallization determination value \textcircled{2} to the abnormal crystallization determination value \textcircled{1} may be about 27.9%. As another example, if the average of row data is calculated at intervals of 1 point in the case of the first trend line and at intervals of 30 points in the case of the second trend line, the ratio of the normal crystallization determination value \textcircled{2} to the abnormal crystallization determination value \textcircled{1} may be about 27.8%.

In this way, the ratio of the normal crystallization determination value \textcircled{2} to the abnormal crystallization determination value \textcircled{1} may be changed by adjusting the number of points for extracting the first trend line and the number of points for extracting the second trend line.

The smaller the ratio of the normal crystallization determination value \textcircled{2} to the abnormal crystallization determination value \textcircled{1}, the better the difference between the abnormal crystallization determination value \textcircled{1} and the normal crystallization determination value \textcircled{2} is represented. Therefore, the first and second trend lines may be extracted using the point interval of a case where the ratio of the normal crystallization determination value \textcircled{2} to the abnormal crystallization determination value \textcircled{1} is the smallest.

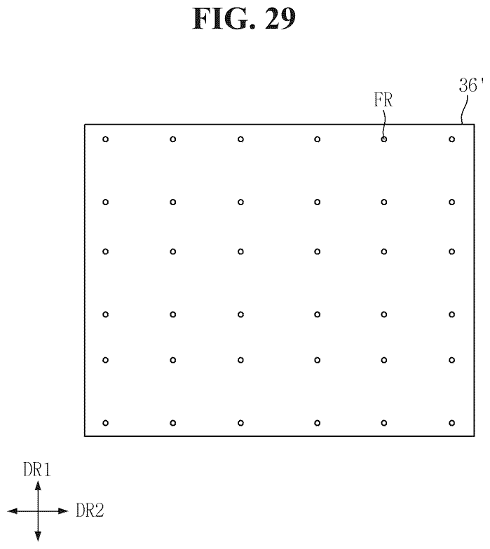

FIG. 28 is a schematic perspective view illustrating operation S210 of FIG. 3. FIG. 29 is a schematic plan view illustrating focus regions FR of a polysilicon target substrate 30′ of FIG. 28.

Referring to FIGS. 28 and 29 in addition to FIGS. 3 and 7, in the manufacturing of the polysilicon target substrate (operation S210), the polysilicon target substrate 30′ may be manufactured using an OPED selected in a previous operation. The polysilicon target substrate 30′ may be different from the test substrate 30 of FIG. 7 at least in that the polysilicon target substrate is manufactured using the OPED. Since other components of the target substrate 30′ of FIG. 28 are the same as those of the test substrate 30 of FIG. 7, a redundant description thereof will be omitted.

As illustrated in FIG. 29, the focus regions FR may also be defined in polysilicon 36′ of the target substrate 30′.

As in the selecting of the optimum inspection value using the test substrate (operation S100), in the determining of the crystallization degree and abnormal crystallization of the target substrate (operation S200), the capturing of the focus region (operation S220) and the quantifying of the crystallization degree and the abnormal crystallization (operation S230) may be performed simultaneously. The capturing of the focus region (operation S220) and the quantifying of the crystallization degree and the abnormal crystallization (operation S230) in the determining of the crystallization degree and abnormal crystallization of the target substrate (operation S200) are the same as the capturing of the focus region (operation S120) and the quantifying of the crystallization degree and the abnormal crystallization (operation S130) in the selecting of the optimum inspection value using the test substrate (operation S100), and thus a redundant description thereof will be omitted.

In the determining of the crystallization degree and the abnormal crystallization (operation S240), the crystal quality determination unit 67 of the control unit 60 may determine crystal quality such as the crystallization degree and abnormal crystallization of the target substrate 30′ by comparing a statistical value of the target substrate 30′ with the previously selected OPED and OACD.

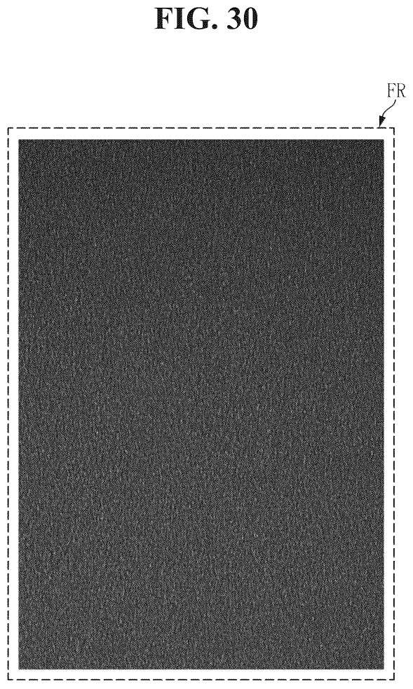

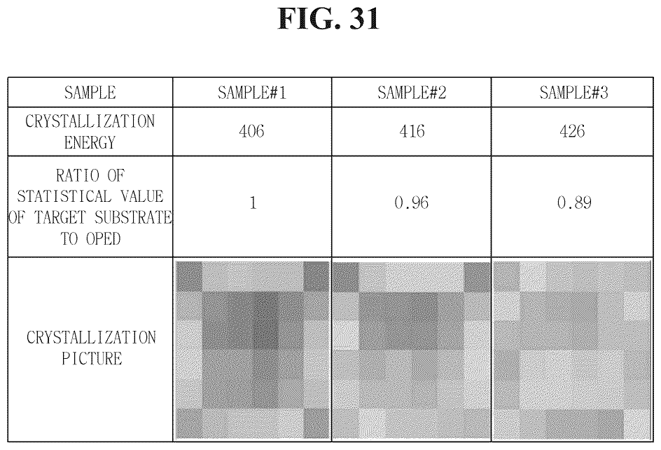

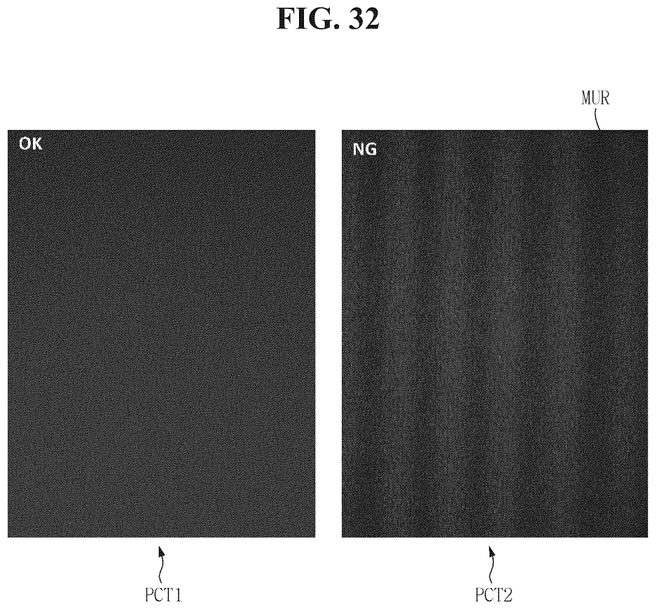

FIG. 30 is a schematic graph of an image of a focus region captured in operation S220 of FIG. 3. FIG. 31 is a schematic table showing crystallization energy, crystallization degree values, and crystallization pictures of various samples of polysilicon target substrates. FIG. 32 is a schematic diagram comparing a captured image of a focus region of an abnormal crystallization substrate and a captured image of a focus region of a normal substrate.

Referring to FIGS. 30 through 32 in addition to FIG. 26, FIG. 30 shows a captured image of one focus region FR. As shown in FIG. 30, determination of the crystallization degree in the focus region FR is not readily performable with the naked eye.

On the other hand, as shown in FIG. 31, it can be seen from the enlarged crystallization pictures of sample #1 through sample #3 that sample #1 has a higher crystallization degree than sample #2, and sample #2 has a higher crystallization degree than sample #3. Here, it can be seen that sample #1 is also higher than sample #2 in the ratio of a statistical value of a target substrate to the OPED, and sample #2 is higher than sample #3. Accordingly, it can be seen that sample #1 has a lower crystallization energy than sample #2, and sample #2 has a lower crystallization energy than sample #3.

As described above, according to the substrate inspection method S1 according to an embodiment, it is possible to objectively calculate crystallization degree and crystallization energy for achieving the crystallization degree by quantifying the crystallization degree.

In addition, FIG. 32 shows a captured image of a normal substrate OK in a first picture PCT1 on the left and a captured image of an abnormal substrate NG in a second picture PCT2 on the right. As shown in FIG. 32, the normal substrate OK may not include vertical mura MUR, and the abnormal substrate NG may include the vertical mura MUR. The normal substrate OK and the abnormal substrate NG of FIG. 32 are captured images of the normal substrate OK and the abnormal substrate NG used for the description of FIG. 26.

As illustrated in FIG. 26, it can be seen that a statistical value (e.g., average or standard deviation) of the normal substrate OK is lower than that of the abnormal substrate NG.

As described above, according to the substrate inspection method S1 according to an embodiment, it is possible to objectively calculate abnormal crystallization by quantifying the abnormal crystallization.

For example, abnormal crystallization such as vertical mura, horizontal mura, diagonal mura, etc. may occur due to misalignment of the configuration of the optical system included in the annealing device 10 (see FIG. 7). By using data obtained by objectively quantifying the misalignment of the configuration of the optical system using line integral data for each angle, it is possible to determine whether abnormal crystallization such as vertical mura, horizontal mura, diagonal mura, etc. has occurred.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

What is claimed is:

1. A substrate inspection method, comprising:
selecting an optimum inspection value using a test substrate; and
determining at least one of crystallization degree and abnormal crystallization of a target substrate using the optimum inspection value,
wherein the selecting of the optimum inspection value comprises:
capturing a focus region located in at least a portion of the test substrate;
quantifying at least one of the crystallization degree and the abnormal crystallization of the test substrate; and
selecting at least one of an optimum process energy density value (OPED) and an optimum abnormal crystallization determination value (OACD) as the optimum inspection value.

2. The method of claim 1, wherein
the quantifying of the at least one of the crystallization degree and the abnormal crystallization of the test substrate comprises quantifying the abnormal crystallization, and
the quantifying of the abnormal crystallization comprises extracting a color table value and calculating a statistical value using the color table value.

3. The method of claim 2, wherein a color table used in the extracting of the color table value is at least one of an RGB color table, a gray color table, a YCbCr color table, and an HSV color table.

4. The method of claim 2, wherein the calculating of the statistical value comprises:
extracting line integral data for each angle in the focus region;
extracting two or more trend lines of the line integral data for each angle; and
calculating a statistical value of the two or more trend lines.

5. The method of claim 4, wherein
the line integral data comprises data obtained by adding color table values of pixels located at a same position in extension lines, and
the extension lines extend at a same angle in the focus region and are arranged side by side with each other in a direction different from the angle.

6. The method of claim 5, wherein the line integral data is extracted for each component of the color table.

7. The method of claim 5, wherein each of the two or more trend lines is a graph of a function generated by connecting a point corresponding to an average of every n pieces of data included in the line integral data, wherein n is a natural number.

8. The method of claim 7, wherein
the two or more trend lines comprise a first trend line and a second trend line,
the first trend line is a graph of a function generated by connecting a point corresponding to an average of every x pieces of data,
the second trend line is a graph of a function generated by connecting a point corresponding to an average of every y pieces of data, and
x and y are natural numbers equal to or less than n and are derived from a case where a ratio of a statistical value of a normal substrate among test substrates to a statistical value of an abnormal substrate among the test substrates is the smallest.

9. The method of claim 4, wherein the statistical value is calculated using the squares of deviations between the two or more trend lines.

10. The method of claim 9, wherein the statistical value is one of the average, standard deviation, maximum value, and minimum value of the squares of the deviations between the two or more trend lines.

11. The method of claim 1, wherein
the selecting of the optimum inspection value further comprises manufacturing the test substrate,
the determining of the at least any of the crystallization degree and abnormal crystallization of the target substrate comprises manufacturing the target substrate, and
the test substrate and the target substrate comprise polysilicon formed by a laser annealer.

12. The method of claim 11, wherein in the manufacturing of the target substrate, crystallization energy of the laser annealer uses the OPED.

13. The method of claim 1, wherein
the determining of the at least any of the crystallization degree and abnormal crystallization of the target substrate comprises:
capturing a focus region located on at least a portion of the target substrate; and
quantifying at least any of crystallization degree and abnormal crystallization of the target substrate,
the capturing of the focus region of the target substrate is performed in a same manner as the capturing of the focus region of the test substrate, and
the quantifying of the at least any of the crystallization degree and abnormal crystallization of the target substrate is performed in a same manner as the quantifying of the at least any of the crystallization degree and abnormal crystallization of the test substrate.

14. A substrate treatment apparatus, comprising:
an annealer which crystallizes amorphous silicon on a substrate into polysilicon;
an imaging assembly which captures a focus region located in at least a portion of the polysilicon; and
a controller which analyzes an image provided by the imaging assembly,
wherein the imaging assembly comprises a dark field microscope and a differential interference contrast microscope.

15. The apparatus of claim 14, wherein the dark field microscope comprises a first light source, a first reflector, a guide, a first objective lens, a first tube lens, and a first camera.

16. The apparatus of claim 14, wherein the differential interference contrast microscope comprises a second light source, a second reflector, a prism, a second objective lens, a second tube lens, and a second camera.

17. The apparatus of claim 16, wherein the prism comprises a refractive prism, and the refractive prism separates light incident from the second light source into at least two beams.

18. The apparatus of claim 17, wherein the at least two beams separated by the prism are reflected at different points in the focus region.

19. The apparatus of claim 16, wherein the dark field microscope comprises a first light source, a first reflector, a guide, a first objective lens, a first tube lens and a first camera, and the first camera and the second camera are configured as one camera.

20. The apparatus of claim 19, wherein the first light source and the second light source, the first reflector and the second reflector, the first objective lens and the second objective lens, and the first tube lens and the second tube lens are configured as one light source, one reflector, one objective lens, and one tube lens, respectively.
